(19) United States
(12) Patent Application Publication
(10) Pub. No.: US 2006/0146612 A1
(43) Pub. Date: Jul. 6, 2006

(54) Flash memory devices configured to output data without waiting for bitline and wordline recovery and methods of operating same

(76) Inventors: Ji-Sook Lim, Gyeonggi-do (KR); Jin-Yub Lee, Seoul (KR)

Correspondence Address: MYERS BIGEL SIBLEY & SAJOVEC, PO BOX 37428, RALEIGH, NC, 27627, US

(21) Appl. No.: 11/222,465

(22) Filed: Sep. 8, 2005

(30) Foreign Application Priority Data
Jan. 3, 2005 (KR) 10-2005-00275

(51) Int. Cl. G11C 16/06

(52) U.S. Cl. 365/185.21

(57) ABSTRACT

A flash memory device includes a memory cell array and an address decoding circuit configured to select bitlines and wordlines of the memory cell array. The device further includes a data sensing circuit configured to read data from a cell of the memory cell array responsive to a selected bitline and wordline and to output the read data without waiting for recovery of the selected bitline and wordline. The data sensing circuit may be configured to output the read data concurrent with recovery of the selected bitline and wordline.

### CROSS-REFERENCE TO RELATED APPLICATIONS

This U.S. non-provisional patent application claims priority under 35 U.S.C. § 119 of Korean Patent Application 2005-00275 filed on Jan. 3, 2005, the disclosure of which is hereby incorporated by reference in its entirety.

### BACKGROUND

The present invention relates to semiconductor memory devices and, more particularly, to flash memory devices and methods of operating the same.

A microprocessor or a microcontroller, used as a memory controller, may be capable of operating at a read cycle time that is shorter than access times of nonvolatile semiconductor memory devices that it may control, such as erasable and programmable ROMs, electrically erasable and programmable ROMs, and flash EEPROMs. For a NAND flash memory device, a memory controller may take data output from the NAND flash memory device in sync with a read enable signal (nRE) after a predetermined time following a transfer of an address and read command (READ CMD) to the NAND flash memory device.

A read operation in the NAND flash memory device is described with reference to FIG. 1 in detail. The NAND flash memory device latches the “00h” command in accordance with a predetermined timing pattern, and sequentially receives column and row addresses in sync with a write enable signal new (“n” means the signal is an active low signal). After receiving the column and row addresses, the NAND flash memory device conducts a sensing operation for a time tR in response to an input of the “30h” command. In the sensing operation, data stored in memory cells of a selected row are transferred to a register. During the sensing operation, the NAND flash memory device maintains a control signal R/nB at a logic low level. The data stored in the register is transferred to data pads (or pins) in units of data bundles (e.g., ×8, ×16, ×32, etc.) in accordance with an input/output data structure of the device. In further detail, when the read enable signal nRE provided from the memory controller transitions to the logic low level from a logic high level, the data stored in the register is transferred to the data pads. When the read enable signal nRE goes to a logic high level from a logic low level, the memory controller reads the data from the data pads. Thus, the outputting of data by the NAND flash memory device and reading of the output data by the memory controller are accomplished all within one cycle of the read enable signal nRE.

This “output and fetch” scheme may serve as a limit on the minimum cycle time of the read enable signal nRE. Because the memory controller (or host) may operate faster than the NAND flash memory device, the performance of the memory controller may be limited by the read performance of the NAND flash memory device. Therefore, it is generally desirable to improve the read performance of the NAND flash memory device.

### SUMMARY OF THE PRESENT INVENTION

According to some embodiments of the present invention, a flash memory device includes a memory cell array and an address decoding circuit configured to select bitlines and wordlines of the memory cell array. The device further includes a data sensing circuit configured to read data from a cell of the memory cell array responsive to a selected bitline and wordline and to output the read data without waiting for recovery of the selected bitline and wordline. The data sensing circuit may be configured to output the read data concurrent with recovery of the selected bitline and wordline. The device may be further configured to transition to a standby state to receive a next command after outputting data from the data sensing circuit. The device may be configured to delay a subsequent read operation until recovery of the selected bitline and wordline is complete.

In further embodiments of the present invention, a flash memory device includes a flash memory unit. The flash memory unit includes a memory cell array, an address decoding circuit configured to select bitlines and wordlines of the memory cell array and a data sensing circuit configured to sense data from a cell of the memory cell array responsive to a selected bitline and wordline. The device further includes a buffer memory configured to store data output by the data sensing circuit and an interface unit configured to provide a data interface between the flash memory unit and the buffer memory and a data interface between the buffer memory and an external host. The data sensing circuit is further configured to provide the sensed data to the buffer memory without waiting for recovery of the selected bitline and wordline. The data sensing circuit may be configured to provide the sensed data to the buffer memory concurrent with recovery of the selected bitline and wordline.

In further embodiments of the present invention, methods of operating a flash memory device are provided. Data is sensed from a bitline coupled to a memory cell responsive to a selected bitline and wordline. The sensed data is output without waiting for recovery of the selected bitline and wordline. The sensed data may be output concurrent with recovery of the selected bitline and wordline. The flash memory device may include a buffer memory configured to receive data from a data sensing circuit, and outputting the sensed data without waiting for recovery of the selected bitline and wordline may include outputting the sensed data from the data sensing circuit to the buffer memory without waiting for recovery of the selected bitline and wordline.

### BRIEF DESCRIPTION OF THE DRAWINGS

The accompanying drawings are included to provide a further understanding of the present invention, and are incorporated in and constitute a part of this specification. The drawings illustrate example embodiments of the present invention and, together with the description, serve to explain principles of the present invention. In the drawings:

FIG. 1 is a timing diagram showing read operations of a conventional NAND flash memory device;

FIG. 2 is a block diagram illustrating a flash memory device according to a some embodiments of the present invention;

FIG. 3 is a block diagram illustrating a flash memory device according to further embodiments of the present invention;

FIG. 4 is a schematic diagram illustrating exemplary read operations of a flash memory device according to additional embodiments of the present invention;

FIG. 5 is a timing diagram illustrating exemplary read operations of the NAND flash memory device shown in FIG. 2 according to some embodiments of the present invention; and

FIG. 6 is a timing diagram illustrating exemplary read operations of the NAND flash memory device shown in FIG. 3 according to further embodiments of the present invention.

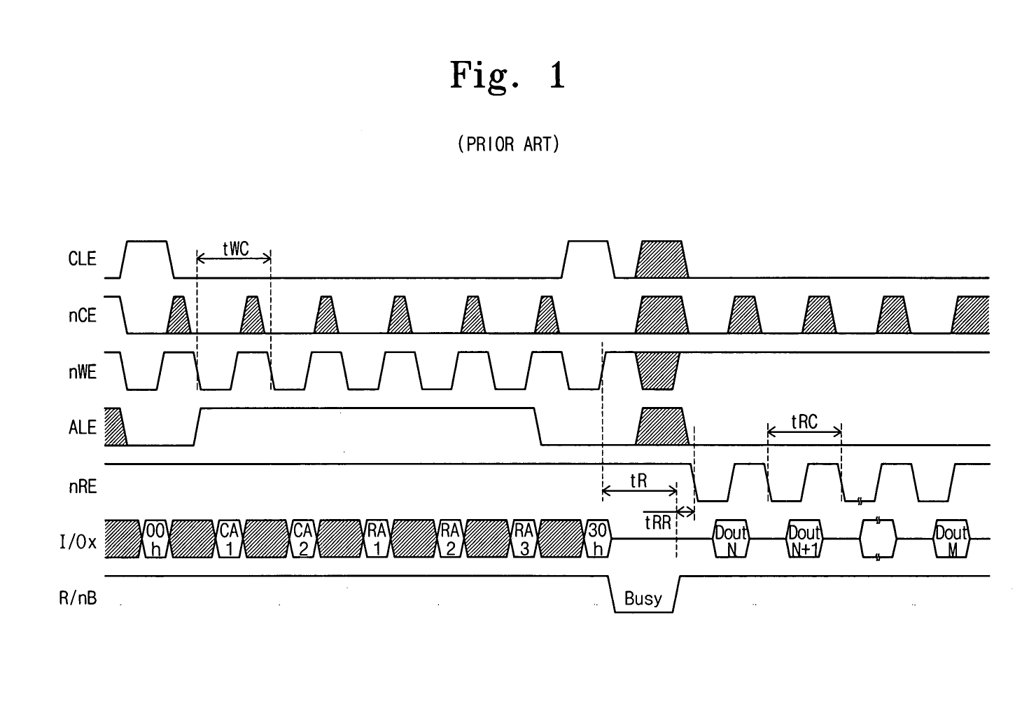

### DETAILED DESCRIPTION OF EXEMPLARY EMBODIMENTS

The present invention is described more fully hereinafter with reference to the accompanying drawings, in which embodiments of the present invention are shown. This invention may, however, be embodied in many different forms and should not be construed as limited to the embodiments set forth herein. Rather, these embodiments are provided so that this disclosure will be thorough and complete, and will fully convey the scope of the present invention to those skilled in the art. In the drawings, the size and relative sizes of layers and regions may be exaggerated for clarity.

It will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present. Like numbers refer to like elements throughout. As used herein, the term “and/or” includes any and all combinations of one or more of the associated listed items.

It will be understood that, although the terms first, second, third etc. may be used herein to describe various elements, components and/or sections, these elements, components and/or sections should not be limited by these terms. These terms are only used to distinguish one element, component, or section from another element, region or section. Thus, a first element, component or section discussed below could be termed a second element, component or section without departing from the teachings of the present invention.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In some embodiments of the present invention, flash memory devices and methods of operation thereof include sensing data by applying voltages to wordlines and bitlines corresponding to decoded row and column addresses for reading. The device outputs the sensed data without waiting for recovery of the wordlines and bitlines. A recovery operation for the wordlines and bitlines is conducted in parallel with output of the sensed data. As a result, a read time of the flash memory device may be reduced.

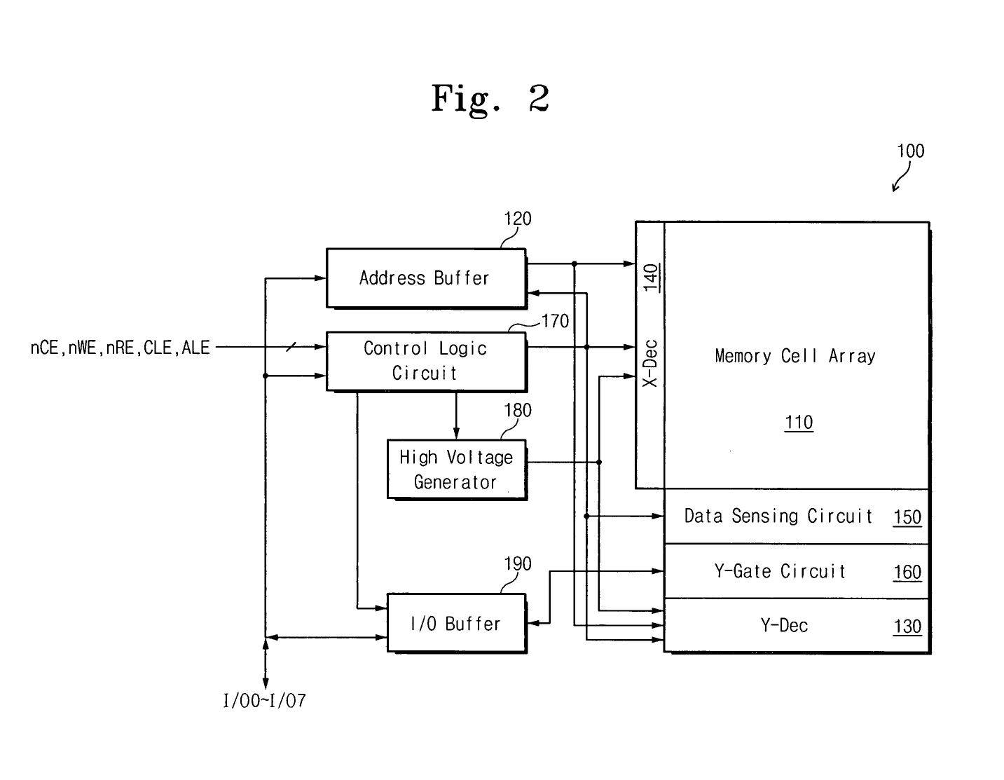

FIG. 2 is a block diagram illustrating a NAND flash memory device 100 according to some embodiments of the present invention. The flash memory device 100 includes a memory cell array 110, an address buffer 120, a Y-decoder 130, an X-decoder 140, a data sensing circuit 150, a Y-gate circuit 160, a control logic circuit 170, a high voltage generator 180, and an input/output buffer 190.

The memory cell array 110 includes a plurality of blocks arranged in units of plural NAND strings (or cell strings). Each string includes a plurality of memory cells connected in series. Each memory cell has floating and control gates, electrically erased and programmed by accumulating electrons in the floating gate and by discharging electrons from the floating gate, respectively. Pluralities of wordlines are used to selectively activate the memory cells. Pluralities of bitlines are connected to the memory cells to selectively input and/or output data.

The X-decoder 140 selects one of the wordlines in response to an externally supplied X-address (i.e., a row address). A wordline voltage is applied to the selected wordline. For instance, during a read operation, a read voltage is applied to a selected wordline while a pass voltage is applied to deselected wordlines. During a program operation, a program voltage is applied to a selected wordline while a pass voltage is applied to deselected wordlines. The high voltage generator 180 supplies the read voltage, the pass voltage, and the program voltage under control of the control logic circuit 170. The high voltage generator 180 may include, for example, a conventional pump circuit. The control logic circuit 170 regulates the program, read, and erase operations of the flash memory device 100 in response to control signals, nCE, new, nRE, CLE, and ALE, supplied from a memory controller (or host), and commands supplied through input/output pins IO0-IO7.

The data sensing circuit 150 is a page buffer circuit including a plurality of latches. The Y-decoder 130 and the Y-gate circuit 160 select the latches of the data sensing circuit 150 in response to externally supplied Y-addresses (i.e., column addresses). The data sensing circuit 150 selects and amplifies data of the memory cells by way of the latches selected by the Y-decoder 130 and the Y-gate circuit 160. As is known, the plurality of latches included in the data sensing circuit 150 may function as page buffers to temporarily store data to be stored in memory cells through their corresponding bitlines in a program operation. In a program verifying operation, the latches may function as verifying detectors to determine if the program operations for memory cells have been successfully completed. In a read operation, the latches act as sense amplifiers for detecting and amplifying data read out from the memory cells. Sensed data stored in the latches of the data sensing circuit 150 are transferred to the input/output buffer 190 through the Y-gate circuit 130.

The operations of reading data by the NAND flash memory device 100 and transferring the data to the memory controller may be accomplished within one cycle of the read enable signal nRE. During the reading period, the flash memory device 100 selects wordlines and bitlines corresponding to decoded row and column addresses, and detects data using the data sensing circuit 150. After detecting data by the data sensing circuit 150, the wordlines and bitlines are returned to their previous original states. Conventionally, the data sensing circuit 150 might output its sensed result after waiting for recovery of the selected wordline and bitline. However, in the illustrated embodiments of the flash memory device 100, the data sensing circuit 150 outputs its sensed result without waiting for recovery of a selected wordline and bitline. Recovery of the wordline and bitline may occur concurrent with outputting data from the data sensing circuit 150. As a result, a read time for data may be reduced, which may enhance the performance of the memory system. Such a recovery operation for the wordline and bitline is referred herein as a “hidden recovery operation.”

NAND flash memories are gaining popularity because of potential merit of high integration density and large storage capacity. However, they typically have disadvantages of longer reading and writing times than random access memories and may be incapable of operating with random access. In order to overcome the demerits of NAND flash memory devices that are incapable of random access, there are new techniques in development, such as the use of a buffer memory to assist the random access operation therein. In some embodiments of the present invention, a hidden recovery scheme is also applicable to a flash memory device that includes an auxiliary memory, such as a buffer memory.

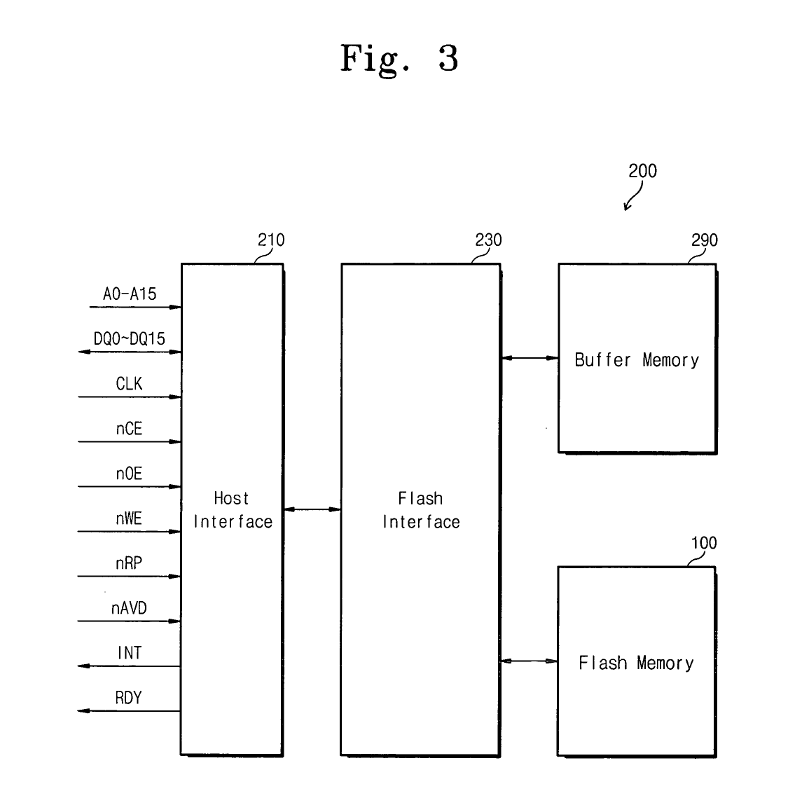

FIG. 3 is a block diagram illustrating a flash memory device 200 according to further embodiments of the present invention. The flash memory device 200 includes an embedded buffer memory 290 configured to provide random access functions. The flash memory device 200 includes a flash memory unit 100, a host interface 210, a flash interface 230, and the buffer memory 290. The flash memory unit 100 may be the same as or similar to the flash memory device shown in FIG. 2, and is configured to provide a hidden recovery operation for the bitline similar to that of the flash memory device 100 described with reference to FIG. 2. The flash memory device 200 of FIG. 3 performs an interface operation with an external memory controller by way of the host interface 210 and performs data input/output operations with the buffer memory 290 by way of the flash interface 230. The flash memory device 200 shown in FIG. 3 transfers data read from the flash memory unit 100 temporarily to the buffer memory 290 using the internal interface of the flash interface 230. In contrast, the flash memory device 100 shown in FIG. 2 outputs a sensed result of the data sensing circuit 150 directly to an external memory controller (or host). Common features between the flash memory devices 100 and 200 include output of data without waiting for the recovery of wordlines and bitlines, which recover according to a hidden recovery scheme as described above.

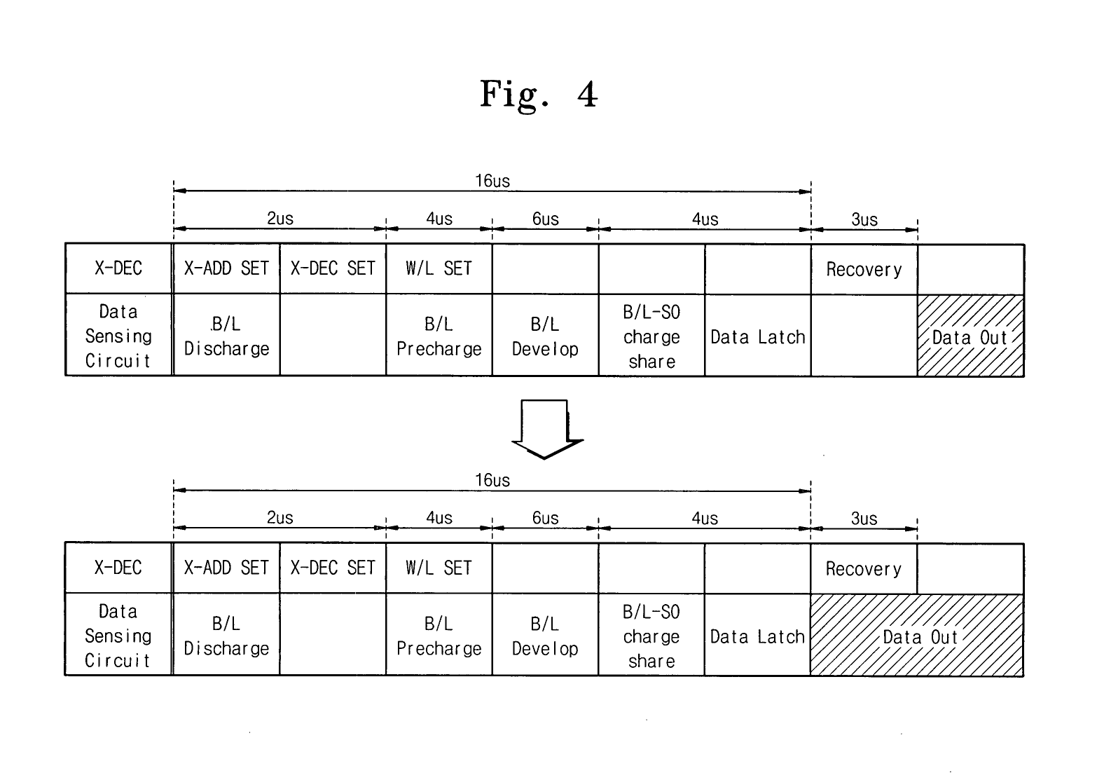

FIGS. 4A and 4B are schematic diagrams illustrating an exemplary read operation timing sequences for a conventional flash memory device in contrast to a flash memory device (e.g., the flash memory devices 100 and 200 of FIGS. 2 and 3) according to some embodiments of the present invention. In each figure, a read command is applied to the flash memory device 100 or 200 and, in response, a data sensing circuit (i.e., page buffer) detects data through a sequence of a bitline discharging operation (for 2 μs), a bitline precharging operation (4 μs), a bitline developing operation (6 μs), a bitline-source charging operation, and a data latching operation (4 μs). As shown, the data sensing operation takes about 16 μs. For the data sensing operation, column and row addresses for a memory cell to be read are provided to the Y- and X-decoders (about 2 μs). Bitlines and wordlines are selected in response to the decoded column and row addresses (4 μs). In a typical specification for a NAND flash memory device, the column address is processed earlier than the row address. Accordingly, FIG. 4 shows the operational timing when the row address is provided to the X-decoder later than the column address.

After detecting data by the data sensing circuit 150 (i.e., after completing data latch operations by the data sensing circuit 150), the bitlines and wordlines recover, which usually takes around 3 μs. In the conventional device operations of FIG. 4A, the data sensing circuit may hold the sense data and output the sensed data after waiting for recovery of the bitlines and wordlines. However, in the operations of FIG. 4B, a flash memory device according to some embodiments of the present invention outputs the data without waiting for such recovery. As shown, the sensed data is output concurrent with recovery for the bitlines and wordlines, i.e., outputting the sense data and recovery of the bitlines and wordlines occur in parallel. As a result, the recovery time (e.g., about 3 μs) may not add to the read time of the flash memory device 100 or 200. In the illustrated case, it takes about 10 μs to output the sensed data.

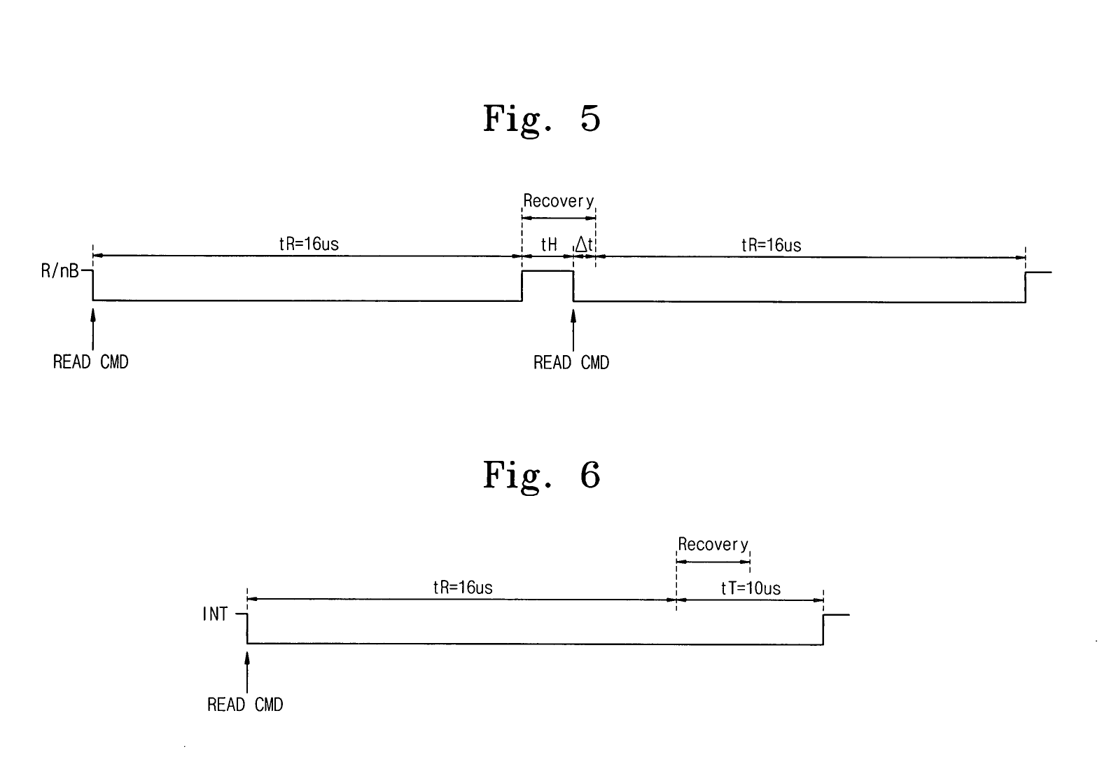

FIG. 5 is a timing diagram illustrating read operations of the flash memory device 100 shown in FIG. 2, and FIG. 6 is a timing diagram illustrating a read operation of the flash memory device 200 shown in FIG. 3. As discussed above, the flash memory device 100 does not have auxiliary memory, while the flash memory device 200 includes auxiliary buffer memory (e.g., a SRAM). Referring to FIG. 5, in the flash memory device 100, the control signal (i.e., ready/busy signal) R/nB goes to a high level to put the device into a standby mode if the data sensing circuit 150 (i.e., page buffer) detects data in response to the read command READ CMD. The sensed data is output to the memory controller (or host) (in a time period tH). Recovery of the wordlines and bitlines occurs concurrent with output of the sensed data. If a new read command READ CMD is input before the recovery of the wordlines and bitlines is complete, the flash memory device 100 waits to execute the new read command READ CMD until after completing the recovery operation, e.g., after a time interval Δt.

Referring to FIG. 6, in the flash memory device 200 of FIG. 2, when the data sensing circuit (i.e., page buffer) thereof detects data in response to the read command READ CMD, recovery of the bitlines and wordlines of the flash memory unit 100 occurs concurrent with output of sensed data to the buffer memory 290. When transfer of the sensed data to the buffer memory 290 is complete (after period tT), an interrupt signal INT goes to a high level to put the flash memory unit 100 into a standby mode. The flash memory unit 100 embedded in the flash memory device 200 outputs the sensed data to the buffer memory 290 responsive to the sensed data being generated by the data sensing circuit 150.

Flash memory devices according to various embodiments of the present invention sense data by applying voltages to wordlines and bitlines corresponding to decoded row and column addresses. Sensed data is output without waiting for recovery of the wordlines and bitlines, and recovery of the wordlines and bitlines is conducted in parallel with output of the sensed data. As a result, a read time of the flash memory devices may be reduced. This can enhance the performance of a memory system employing such devices.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The present invention is defined by the following claims, with equivalents of the claims to be included therein.

What is claimed is:

1. A flash memory device comprising:
a memory cell array;
an address decoding circuit configured to select bitlines and wordlines of the memory cell array; and
a data sensing circuit configured to read data from a cell of the memory cell array responsive to a selected bitline and wordline and to output the read data without waiting for recovery of the selected bitline and wordline.

2. The flash memory device of claim 1, wherein the data sensing circuit is configured to output the read data concurrent with recovery of the selected bitline and wordline.

3. The flash memory device of claim 1, configured to transition to a standby state after outputting data from the data sensing circuit.

4. The flash memory device of claim 3, configured to delay a read operation until recovery of the selected bitline and wordline is complete.

5. A flash memory device comprising:
a flash memory unit comprising:
a memory cell array;
an address decoding circuit configured to select bitlines and wordlines of the memory cell array; and
a data sensing circuit configured to sense data from a cell of the memory cell array responsive to a selected bitline and wordline;
a buffer memory configured to store data output by the data sensing circuit; and
an interface unit configured to provide a data interface between the flash memory unit and the buffer memory and a data interface between the buffer memory and an external host,
wherein the data sensing circuit is further configured to provide the sensed data to the buffer memory without waiting for recovery of the selected bitline and wordline.

6. The flash memory device of claim 5, wherein the data sensing circuit is configured to provide the sensed data to the buffer memory concurrent with recovery of the selected bitline and wordline.

7. The flash memory device of claim 1, configured to transition to a standby state after outputting the data from the data sensing circuit.

8. A method of operating a flash memory device, the method comprising:
sensing data from a bitline coupled to a memory cell responsive to a selected bitline and wordline; and
outputting the sensed data without waiting for recovery of the selected bitline and wordline.

9. The method of claim 8, wherein outputting the sensed data without waiting for recovery of the selected bitline and wordline comprises outputting the sensed data concurrent with recovery of the selected bitline and wordline.

10. The method of claim 8, further comprising putting the device into a standby state after outputting the data.

11. The method of claim 10, wherein, if the next command is input before completing the recovery operation in the standby state, execution of the next command is delayed until the recovery of the selected bitline and wordline is complete.

12. The method of claim 8, wherein the flash memory device comprises a buffer memory configured to receive data from a data sensing circuit, and wherein outputting the sensed data without waiting for recovery of the selected bitline and wordline comprises outputting the sensed data from the data sensing circuit to the buffer memory without waiting for recovery of the selected bitline and wordline.

13. The method of claim 12, wherein the outputting the sensed data from the data sensing circuit to the buffer memory occurs concurrent with recovery of the selected bitline and wordline.

14. The method of claim 12, further comprising putting the device into a standby state after outputting the sensed data to the buffer memory.
